(19) United States
(12) Patent Application Publication
(10) Pub. No.: US 2025/0124964 A1
(43) Pub. Date: Apr. 17, 2025

(54) APPARATUSES AND METHODS FOR PER ROW ACTIVATION COUNTER TESTING

(71) Applicant: Micron Technology, Inc., Boise, ID (US)

(72) Inventors: Yang Lu, Boise, ID (US); Donald M. Morgan, Boise, ID (US)

(73) Assignee: Micron Technology, Inc., Boise, ID (US)

(21) Appl. No.: 18/745,068

(22) Filed: Jun. 17, 2024

Related U.S. Application Data
(60) Provisional application No. 63/589,733, filed on Oct. 12, 2023.

(51) Int. Cl. G11C 11/406

(52) U.S. Cl. CPC G11C 11/406

(57) ABSTRACT

Apparatuses and methods per row activation counter testing (PRACT). A memory includes an aggressor detector circuit, which determines a row address to be an aggressor address after the row address is accessed a number of times. In a normal mode the address is an aggressor after a first number of activations, while in a PRACT mode the address is an aggressor after a second (generally lower) number of activations. For example, when the row is accessed a first value may be added to a count in the normal mode and a second (generally larger) value in the PRACT mode. When the count crosses a threshold, the row is an aggressor.

### CROSS REFERENCE TO RELATED APPLICATION(S)

This application claims the benefit under 35 U.S.C. § 119 of the earlier filing date of U.S. Provisional Application No. 63/589,733 filed Oct. 12, 2023, the entire contents of which are hereby incorporated by reference in its entirety, for any purpose.

### BACKGROUND

Information may be stored on memory cells of a memory device. The memory cells may be organized at the intersection of word lines (rows) and bit lines (columns). Information in the memory cells may decay over time. For example, the information may be stored as a charge on a capacitor which may decay over time. The memory device may perform refresh operations to restore the information and prevent information from being lost.

Certain patterns of access may cause an increased rate of information decay in nearby memory cells (e.g., the memory cells along nearby word lines). Memory devices may use various schemes to identify these access patterns so that additional targeted refresh operations may be performed. It may be useful to be able to test the function of such schemes in order to ensure they are working as intended.

### BRIEF DESCRIPTION OF THE DRAWINGS

FIG. 1 is a block diagram of a semiconductor device according to an embodiment of the present disclosure.

FIG. 2 is a block diagram of a refresh control circuit according to an embodiment of the present disclosure.

FIG. 3 is a schematic diagram of an aggressor detector circuit with a PRACT circuit which modifies the threshold according to some embodiments of the present disclosure.

FIG. 4 is a schematic diagram of an aggressor detector circuit with a PRACT circuit which modifies which portion of the count value is compared to the threshold according to some embodiments of the present disclosure.

FIG. 5 is a schematic diagram of an aggressor detector circuit with a PRACT circuit which modifies how much the count value is adjusted according to some embodiments of the present disclosure.

FIG. 6 is a timing diagram of example behaviors of an aggressor detector circuit according to some embodiments of the present disclosure.

FIG. 7 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated based on a row address and then selected memory cells along that active word line may have their information read or written to based on which bit lines are accessed, which may be based on a column address. The memory array may be refreshed on a row by row basis (e.g., as part of an auto-refresh and/or self-refresh mode) where the memory cells along each row are refreshed periodically. The speed at which the rows are refreshed (e.g., the maximum time any given row will go between refreshes) may be determined based on an expected rate of information decay.

Various patterns of access to a row (an aggressor row) may cause an increased rate of information decay in nearby memory cells (e.g., along victim rows). For example, a ‘row hammer’ may involve repeated accesses to the aggressor row which may increase a rate of decay in adjacent rows (and/or in rows which are further away). Accordingly, it may be important to track a number of accesses to each row to determine if they are aggressors, such that the victim rows can be identified and refreshed as part of a targeted refresh operation. For example, each word line may have an associated count value which is used to determine how many times that word line has been accessed.

Some memories may use a per-row hammer tracking (PRHT) scheme or a per row activation counter (PRAC) scheme, where each word line has an associated count value used to determine how many times that word line has been accessed. When the row is accessed the count may be changed (e.g., incremented) by a counter circuit and compared to a mitigation threshold by a comparator. If the count crosses the mitigation threshold, then the address may be added to an aggressor queue and during targeted refresh operations, the addresses in the queue are used to generate refresh addresses. There may be a need to test the operation of this system to ensure that addresses are being added to the queue for refreshing.

The present disclosure is drawn to apparatuses, systems, and methods for PRAC testing (PRACT). A memory may be placed in a PRACT mode. During the PRACT mode, a PRACT circuit changes the operation of an aggressor detector circuit so that fewer activations are required to add a word line's address to the aggressor queue than when the PRACT mode is disabled. In this manner, the device may be placed in a PRACT mode, and test activations may be sent which will relatively quickly add the address to the queue (or not, depending on the outcome of the test). There are several ways this may be accomplished.

In an example embodiment, the mitigation threshold may be changed during the testing mode. For example, the PRACT circuit may include a multiplexer which provides either a first threshold or a second threshold to a comparator. The first threshold may be used in normal operation and the second threshold may be used in a PRACT mode. The second threshold may be lower than the first threshold.

In another example embodiment, the bits of the count value may be truncated and compared to (all or a portion of) the threshold. For example, the comparator may be a partial bit comparator which only compares a portion of the bits of the count value to the most significant bits (MSB) of the threshold. The PRACT circuit may include a multiplexer which provides the MSB of the count value in a normal mode or the least significant bits (LSB) of the count value in the PRACT mode. By comparing the LSB of the count to the MSB of the threshold, fewer activations are required to cross the threshold.

In another example embodiments, the amount that the count value is updated by may be changed during the test mode. The PRACT circuit may cause the counter to add a first number to the count each time a word line is activated in a normal mode and to add a second number to the count each time a word line is activated in the PRACT mode. The second number may be larger than the first. In some embodiments, the operation of a row clobber circuit, which adds to the count if a row is open over time may be modified to take advantage of an existing circuit which modifies the count value.

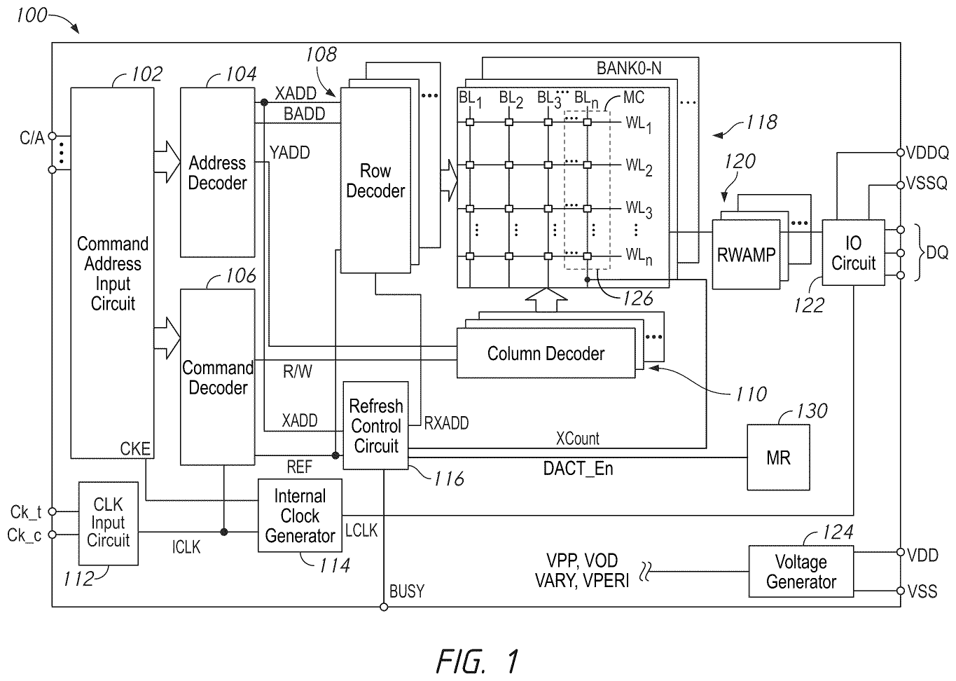

FIG. 1 is a block diagram of a semiconductor device according to at least one embodiment of the disclosure. The semiconductor device 100 may be a semiconductor memory device, such as a DRAM device integrated on a single semiconductor chip.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL (rows), a plurality of bit lines BL (columns), and a plurality of memory cells MC arranged at intersections of the plurality of word lines WL and the plurality of bit lines BL.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL.

Some of the memory cells may be set aside as counter memory cells 126. The counter memory cells may store count values XCount, each of which is associated with one of the word lines. Each count value XCount may be stored in counter memory cells 126 along the word line that the count value is associated with. The count value XCount may be stored as a binary number, with each bit stored in a memory cell along the word line. For the sake of clarity, a single bit line of counter memory cells 126 is shown in FIG. 1. The number of counter memory cells along each word line may be based on a number of bits of the count value XCount. In some embodiments, extra counter memory cells (e.g., more than the length of the number XCount) may be used, for example to store error correction information for the count value XCount.

The counter memory cells 126 may be referred to as such due to their use (storing the count values) and in some embodiments may be structurally similar to, or identical to, the other memory cells of the array. In some embodiments, the counter memory cells 126 may be grouped together (e.g., at the end of the word line). Other distributions of the counter memory cells 126 along the word line may be used in other example embodiments. In some embodiments, the counter memory cells 126 may not be directly accessible by external devices such as controllers (e.g., to prevent the count values from being overwritten). In other words, the bit lines associated with the counter memory cells 126 may not be accessed by a normal column address.

The semiconductor device 100 may employ a plurality of external terminals that include command and address (C/A) terminals coupled to a command and address bus to receive commands and addresses, and a CS signal, clock terminals to receive clocks CK and/CK, data terminals DQ to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The device 100 may receive an access command which is a row activation command ACT. When the row activation command ACT is received, a bank address BADD and a row address XADD are timely supplied with the row activation command ACT.

The device 100 may receive an access command which is a read command. When a read command is received, a bank address BADD and a column address YADD are timely supplied with the read command, read data is read from memory cells in the memory array 118 corresponding to the row address XADD and column address YADD. The read command is received by the command decoder 106, which provides internal commands so that read data from the memory array 118 is provided to the read/write amplifiers 120. The read data is output to outside from the data terminals DQ via the input/output circuit 122. The access count XCount stored in the counter memory cells 126 of the row associated with the row address XADD are read to the refresh address control circuit 116, and an updated value of the access count XCount is written back to the counter memory cells 126 of the row XADD.

The device 100 may receive an access command which is a write command. When the write command is received, a bank address BADD and a column address YADD are timely supplied with the write command, write data supplied to the data terminals DQ is written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC. Similar to the read operation described above, the access count Xcount stored in counter memory cells 126 of the row associated with the row address XADD are read to the refresh address control circuit 116, and an updated value of the access count Xcount is written back to the counter memory cells 126 of the row XADD.

The device 100 may also receive commands causing it to carry out refresh operations. For example, a controller of the memory may put the device 100 into an auto-refresh mode and provide an refresh signal REF. The device 100 may also enter a self-refresh mode where the refresh signal is generated internally. Responsive to the refresh signal REF, one or more refresh operations are performed. Since other than the source of the refresh signal, the two operations may generally be similar, the present disclosure will generally describe auto-refresh operations (for example the refresh signal may be referred to as an ‘auto-refresh signal’). However, it should be understood that the present disclosure may apply to self-refresh (or other refresh modes) as well.

Responsive to the refresh signal REF, the refresh control circuit 116 performs one or more refresh operations by providing a refresh address RXADD, along with refresh signals (not shown in FIG. 1) to the row decoder 108. The row decoder 108 refreshes the word line(s) associated with the refresh address, for example by restoring a charge in the memory cells along the word line(s) to an initial value associated with the value of the bit stored in that memory cell.

When the refresh control circuit 116 performs refresh operations responsive to REF, it determines if the refresh operations are normal (or sequential) refresh operations or targeted refresh operations, or combinations thereof. In a normal refresh operation, the refresh address RXADD is generated based on a sequence of addresses. In other words the refresh address may be generated based on a previous value of the refresh address (e.g., RXADD(i)=RXADD(i−1)+1). The sequence logic used to generate the normal refresh addresses may cycle through each of the word lines of the memory array 118. In a targeted refresh operation, the refresh address RXADD is generated based on an identified aggressor address stored in a targeted refresh queue of the refresh control circuit 116. The refresh address RXADD may represent victim addresses, which may be associated with word lines which have a spatial relationship with the word line associated with the identified aggressor address. For example, the refresh address RXADD may be word lines adjacent to the aggressor word line (e.g., RXADD=Aggressor+/−1). Other relationships (e.g., +/−2, +/−3, +/−4, etc.) may also be used.

In some embodiments, the normal refresh address may be associated with a different number of word lines than the targeted refresh address. The normal refresh address may be associated with more word lines than the targeted refresh address. For example, the normal refresh address may be truncated (compared to a row address XADD) and be associated with all the word lines whose addresses share the value of that truncated portion in common, while the targeted refresh address may be associated with a single word line.

The refresh control circuit 116 includes an aggressor detector circuit which identifies aggressor addresses based on the count value XCount associated with that address. If the address is identified as an aggressor, it is added to the targeted refresh queue for future targeted refresh operations.

When an address is received and the corresponding word line is accessed, the count value XCount associated with that word line is read out from the counter memory cells 126 to the refresh control circuit 116. The aggressor detector updates the count value and compares the updated count value to a threshold. If the count value has not crossed the threshold, then updated count value is written back to the counter memory cells 126. If the count value has crossed the threshold, then the address is added to the targeted refresh queue and the count value is reset (e.g., to an initial value such as 0) and the reset count value is written back as the updated count value.

The aggressor detector circuit includes a PRACT circuit, which alters the behavior of the aggressor detector circuit. As explained in more detail herein, when the device is not in the PRACT mode, aggressor detector circuit may add an address to the queue after the address is received a first number of times, while in the PRACT mode, the address may be added after being received a second number of times. The second number may be less than the first number.

The memory device 100 includes one or more registers where information and/or settings of the device 100 are stored. For example, FIG. 1 shows a mode register 130, which includes a number of registers which may be used to store settings, properties, measured quantities, etc. related to the operation of the memory 100. The memory device 100 may be placed in a PRACT mode. For example, a PRACT register of the mode register 130 may have a value which indicates if the device is in the PRACT mode or not. If the register is set to an inactive state, then the device is not in a PRACT mode (e.g., is in a normal operational mode). If the register is set to an active state, then the device is in a PRACT mode. When the device is in the PRACT mode, the mode register 130 provides a PRACT enable signal PRACT_En. The PRACT circuit changes the behavior of the aggressor detector circuit based on the state of the PRACT enable signal PRACT_En.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

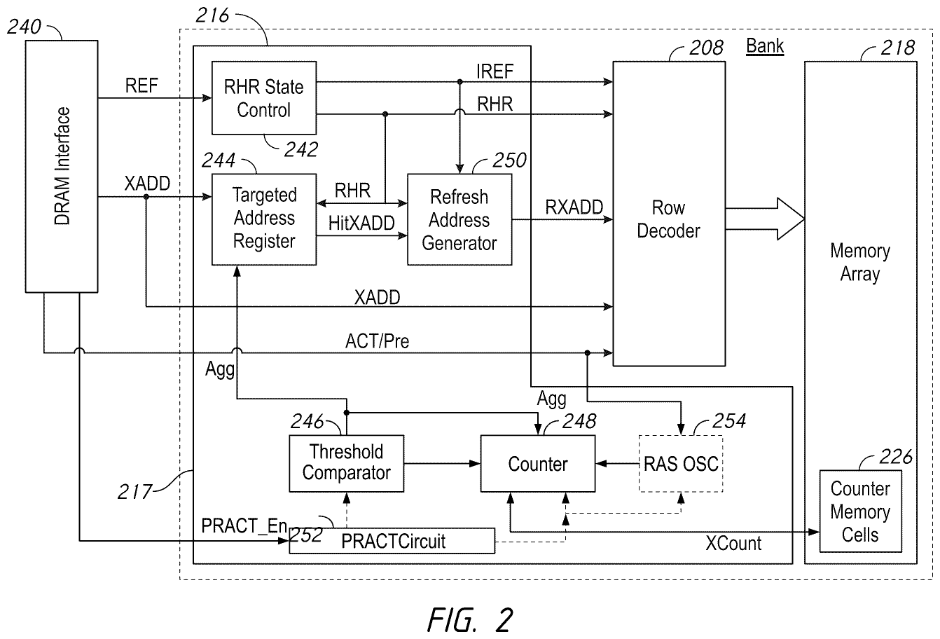

FIG. 2 is a block diagram of a refresh control circuit according to an embodiment of the present disclosure. FIG. 2 may show an example layout which may implement a portion of a memory device, such as the memory device 100 of FIG. 1. For example, the memory array 218 may implement the memory array 118 of FIG. 1, the row decoder 208 may implement the row decoder 108 of FIG. 1, and the refresh control circuit 216 may implement the refresh control circuit 116 of FIG. 1.

Certain internal components and signals of the refresh address control circuit 216 are shown to illustrate the operation of the refresh address control circuit 216. For example, the refresh control circuit 216 may include an RHR state control circuit 242 which determines if sequential or targeted refreshes are performed, an aggressor address register or targeted address queue 244 which stores identified aggressor addresses, a refresh address generator 250 which generates the refresh address RXADD, and an aggressor detector circuit 217 which determines if an address XADD should be added to the targeted refresh queue 244 or not. The aggressor detector circuit 217 includes a counter circuit 248 which updates the count values XCount, a threshold comparator circuit 246 which compares the updated count value to a mitigation threshold, an optional oscillator counter circuit 254 which may be used to add time dependent behavior to how the counts are updated, and a PRACT circuit 252, which may alter the behavior of one or more other components of the aggressor detector circuit 217 when the device is in a PRACT mode.

The dotted line around the refresh address control circuit 216, the row decoder 208, and the memory array 218 is shown to represent that in certain embodiments, each of the components within the dotted line may correspond to a particular bank of memory, and that these components may be repeated for each of the banks of memory. In some embodiments, the components shown within the dotted line may be associated with each of the memory banks. Thus, there may be multiple refresh address control circuits 216 and row decoders 208. For the sake of brevity, components for only a single bank will be described.

The DRAM interface 240 may represent one or more components which provides signals to components of the bank. In some embodiments, the DRAM interface 240 may represent components such as the command address input circuit 102, the address decoder 104, and/or the command decoder 106 of FIG. 1. The signals and addresses provided by the DRAM interface 240 may represent signals, commands, addresses, etc. from an external source (e.g., from a controller) and/or from internal sources (e.g., signals generated internal to the memory).

The DRAM interface 240 provides signals and/or addresses which indicate access operations or refresh operations. For example, the interface 240 may provide a row address XADD along with a row activation signal ACT. Responsive to the signal ACT, the row decoder 208 activates a word line of the memory array associated with XADD so that the memory cells along that word line can be accessed. Responsive to a pre-charge signal Pre, the row decoder deactivates the word line at the end of the access operation. The DRAM interface 240 also provides a refresh signal REF. Responsive to the refresh signal, the refresh control circuit 216 performs one or more refresh operations by providing one or more refresh addresses RXADD along with internal refresh signals IREF and/or RHR. The row decoder 208 refreshes the word line(s) associated with RXADD responsive to IREF/RHR. The DRAM interface also provides a PRACT mode enable signal PRACT_En, which indicates if the PRACT mode is enabled or not. The state of PRACT_En may be based on a state of a PRACT register in a mode register such as 130 of FIG. 1.

The refresh state control circuit 242 may receive the refresh signal REF and provide the internal refresh signal IREF and/or the row hammer refresh (or targeted refresh) signal RHR. The refresh signal REF may be periodically generated (e.g., either by a controller in an auto-refresh mode or by the memory in a self-refresh mode) and may be used to control the timing of refresh operations. The refresh state control circuit 242 determines how many refresh operations to perform responsive to REF and what types of refresh operation should be performed. For example, the signal IREF alone may indicate a normal refresh operation, while the signals IREF and RHR together may indicate a targeted refresh operation.

The refresh state control circuit 242 may use internal logic to determine when to perform the different types of refresh operation. For example, responsive to each refresh signal REF, the refresh state control circuit 242 may perform N refresh operations or ‘pumps’. The pumps may be broken down into some number of targeted refresh operations and some number of normal refresh operations. Other patterns may also be used, for example every M times that a normal refresh operation is performed a targeted refresh operation may be performed instead. Although not discussed in detail herein, more complicated logic which allows the refresh state control circuit 242 to selectively skip refresh operations, change the number of refresh operations per refresh signal and/or alter the ratio of normal and targeted refresh operations may also be used. In some embodiments, the memory may receive a refresh management command RFM. For example, the controller may issue the RFM command. Responsive to the RFM command, the refresh state control circuit 242 may perform one or more targeted refresh operations.

During a normal refresh operation, the refresh address generator 250 may provide a normal refresh address as RXADD. The normal refresh address is generated using sequence logic. For example, each normal refresh address may be generated based on a previous normal refresh address. In an example implementation, the refresh address generator 250 may include a counter circuit which updates (e.g., increments) the previous normal refresh address to generate the next normal refresh address.

During a targeted refresh operation, the refresh address generator 260 provides one or more targeted refresh addresses as RXADD. The targeted refresh addresses are based on an aggressor address HitXADD from the targeted refresh queue 244. The refresh address may represent a word line which has a spatial relationship with the word line associated with the address HitXADD. For example, the refresh address generator 250 may generate two refresh addresses HitXADD which represent the word lines adjacent to the word line associated with HitXADD (e.g., RXADD=HitXADD+/−1). The refresh address generator may additionally or instead generate addresses with different spatial relationships such as HitXADD +/−2, +/−3, +/−4, etc.

The targeted refresh queue 244 is a register which stores a number of addresses. For example, the targeted refresh queue 244 may include a number of content addressable memory (CAM) cells organized into slots. Each slot can store an address. Responsive to an aggressor signal Agg from the aggressor detector circuit 217, the current row address XADD is added to the targeted refresh queue 244. Responsive to the signal RHR, the targeted refresh queue 244 provides a stored address as the aggressor address HitXADD. When an address is used for targeted refresh operations, it is removed from the queue 244. In some embodiments, the queue 244 may act as a FIFO queue.

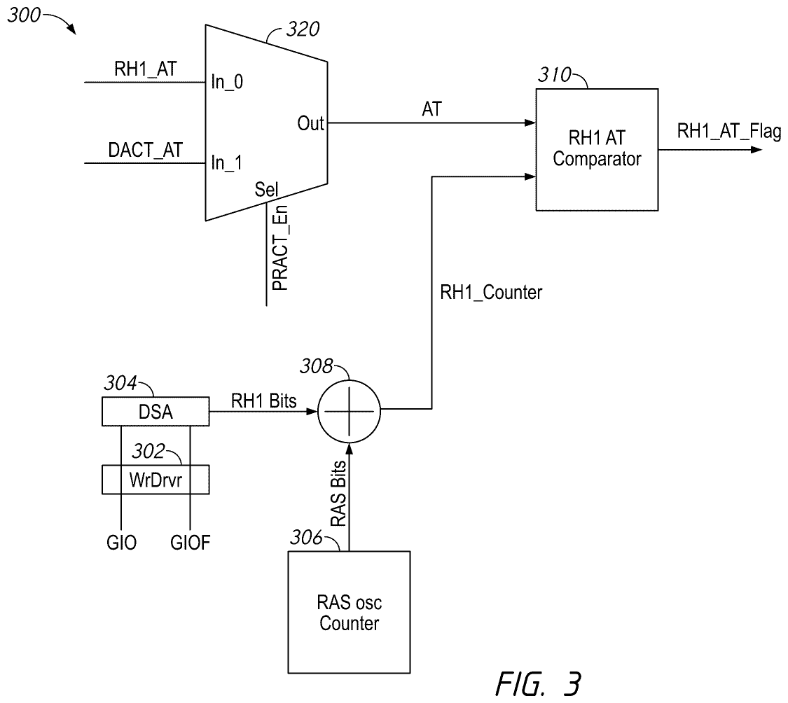

The aggressor detector circuit 217 provides a signal Agg when the current address XADD is determined to be an aggressor. The aggressor detector circuit 217 determines if an address is an aggressor based on the comparison of the count value XCount associated with that address XADD to a threshold. The aggressor detector circuit 217 includes a PRACT circuit 252 which may alter the operation of the aggressor detector circuit 217. Examples of the interaction of the aggressor detector circuit and PRACT circuit are shown in more detail in FIGS. 3-5. For the sake of comparison, FIG. 2 will generally be described with respect to operation in a normal mode (e.g., when PRACT_En is inactive).

When a word line is accessed by the row decoder 218 the counter memory cells 226 along that word line have their stored value read out as the count value XCount. The count value XCount is provided to a counter circuit 248, which updates the count value. For example, the count value may be incremented. A threshold comparator 246 compares the updated count value to a mitigation threshold or attack threshold AT. If the count value has not crossed the threshold (e.g., the updated count is below AT) then the count value is written back to the counter memory cells 226 along the active word line. If the count value has crossed the threshold (e.g., the updated count value is equal to or greater than AT) then the signal Agg is provided, and the count value is reset to an initial value (e.g., 0). The reset count value is written back to the counter memory cells 226 along the active word line.

In some embodiments, the aggressor detector circuit 217 may include an optional oscillator counter circuit 254. The oscillator counter circuit may be begin counting oscillations (e.g., rising edges) of an oscillating signal when the word line is activated. The oscillating signal may be generated by an oscillator circuit of the oscillator counter circuit 254 or may be based on one or more clock signals of the memory. Based on a number of oscillations counted, the counter circuit 248 may instructed to update the count value again, even during a same access to the word line. In other words, the count value may be changed when it is first accessed, and the then changed again at a rate determined by the period of the oscillating signal as long as it remains active. This may allow for detection of ‘clobber’ attacks where a row is held open for a long time.

The PRACT circuit may alter the behavior of the aggressor detector circuit 217 to reduce a number of activations required to add an address to the target refresh queue 244. For example, the PRACT circuit may change the behavior of the threshold comparator circuit 246, the counter circuit 248 and/or the oscillator counter circuit 254 when the signal PRACT_En is active (e.g., when the device is in a PRACT mode).

In an example test procedure, a test platform (e.g., a controller, a tester, a self-test, or combinations thereof) may place the device is a PRACT mode. The test platform provides a sequence of addresses, which includes activating a test address a number of times in a row. The test platform may check the status of the targeted refresh queue to ensure that the test address was added to the queue 244. In the PRACT mode, the number of times the test address must be accessed to add it to the queue 244 is less than the number of times the address would need to be accessed to be added to the queue 244 in the normal mode.

FIGS. 3-5 are example implementations of an aggressor detector circuit showing different example ways the PRACT circuit may alter the operation of the aggressor detector. Since the aggressor detector circuits may generally be similar across FIGS. 3-5, certain details explained with respect to one of FIGS. 3-5 may not be repeated for others of FIGS. 3-5 for the sake of brevity.

FIG. 3 is a schematic diagram of an aggressor detector circuit with a PRACT circuit which modifies the threshold according to some embodiments of the present disclosure. The aggressor detector circuit 300 may, in some embodiments, implement the aggressor detector circuit 116 of FIGS. 1 and/or 217 of FIG. 2. The aggressor detector circuit 300 shows an example implementation where the PRACT circuit (e.g., 252 of FIG. 2) includes a multiplexer 320 which changes the attack threshold AT.

The view of FIG. 3 includes some components of the memory array (e.g., 118 of FIGS. 1 and/or 218 of FIG. 2) such as the word line driver 302 and sense amplifier 304. The word line driver 302 activates a word line responsive to signals from the row decoder. Information on memory cells along the active word line are accessed along global input/output lines GIO and GIOF from the local input/output lines and bit lines. In this case the sense amplifier 304 is coupled to the bit lines which intersect the counter memory cells. Accordingly, when the word line driver 304 activates a word line, the sense amplifier 304 provides the bits of the count value XCount, here annotated as RH1 bits.

The aggressor detector circuit 300 includes a counter circuit 308 (e.g., 248 of FIG. 2), which receives the count value bits RH1 Bits. The counter circuit 308 updates the count value, for example by incrementing the count represented by the RH1 bits. The updated count value RH1_Counter is provided to a comparator 310. In the example embodiment of FIG. 3, the counter circuit 308 may be an adder circuit which sums the count value RH1 Bits and an access time signal RAS Bits provided by the oscillator counter circuit 306. The oscillator counter circuit 306 may initialize the access time signal RAS Bits at 1, so the updated count value RH1_Counter will be at least incremented compared to the count value RH1 Bits.

The oscillator counter circuit 306 increases the value of RAS Bits over time while the word line is active. When the word line is activated, the oscillator counter circuit 306 begins counting oscillations of a periodic signal. Each time the signal oscillates the signal RAS Bits is increased (e.g., by being incremented). Accordingly, the signal RAS Bits has a value which represents an amount of time which has passed since the row was activated. Accordingly, since RH1_Counter is the sum of RH1 Bits and RAS Bits, the updated count value RH1_Counter will also increase with time.

In some embodiments, when the signal PRACT_En is active (e.g., in the PRACT mode) the value of RAS Bits may be set to ‘1’ no matter how much time passes. This may allow for testing of the functionality of the aggressor detector circuit 300 based on accesses alone, without adding extra variable such as time. In some embodiments, the oscillator counter circuit 306 may be omitted, and the counter circuit 308 may add a ‘1’ (or some other fixed value) to RH1 Bits without time being a factor.

The comparator 310 compares the updated count value RH1_Counter to the aggressor threshold AT. If the updated count RH1_Counter is below the threshold AT, then the count RH1_Counter is written back to the counter memory cells. IF the updated count value RH1_Counter is at or above the threshold AT, then the aggressor signal Agg, here shown as RH1_AT_Flag is provided and the address is identified as an aggressor.

In the embodiment of FIG. 3, the PRACT circuit includes a multiplexer 320 which sets a value of the threshold AT. The multiplexer 320 has input terminals which receive a row hammer threshold RH1_AT and a testing threshold PRACT_AT and a switch terminal which receives PRACT_En. When PRACT_En is inactive (e.g., at a low logical level) the threshold RH1_AT is provided as AT. When PRACT_En is active (e.g., at a high logical level) the test threshold PRACT_AT is provided as AT.

The threshold RH1_AT is greater than the test threshold PRACT_AT. In this manner, when the signal PRACT_En is active, the threshold AT is reduced, and fewer activations (e.g., a smaller value of RH1_Counter) is required before the signal RH1_AT_Flag is provided.

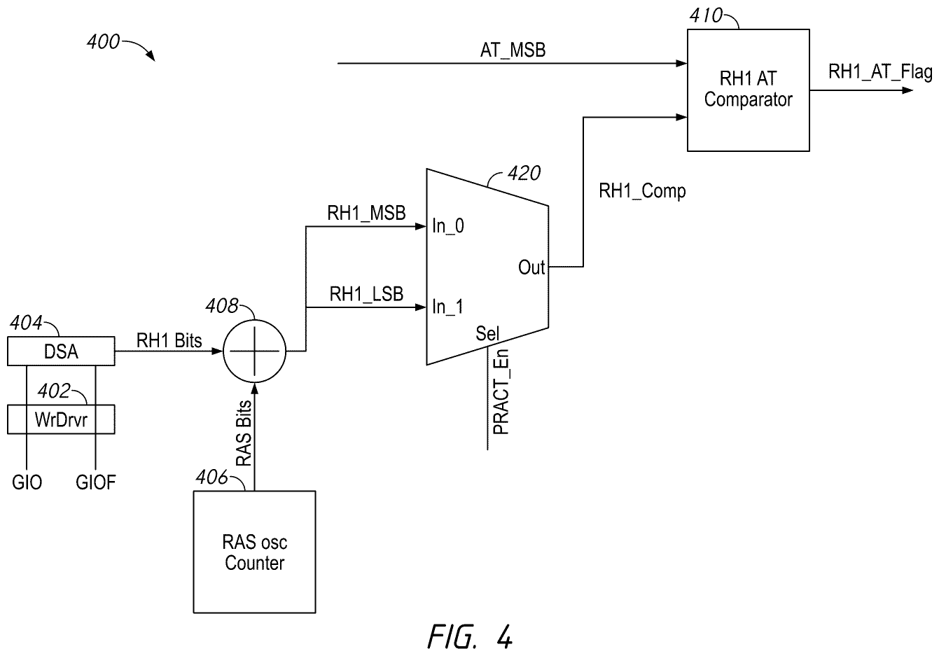

FIG. 4 is a schematic diagram of an aggressor detector circuit with a PRACT circuit which modifies which portion of the count value is compared to the threshold according to some embodiments of the present disclosure. The aggressor detector circuit 400 may, in some embodiments, implement the aggressor detector circuit 116 of FIGS. 1 and/or 217 of FIG. 2. The aggressor detector circuit 400 shows an example implementation where the PRACT circuit (e.g., 252 of FIG. 2) includes a multiplexer 420 which changes which portion of the bits of the count value is provided to the comparator 410.

Similar to the aggressor detector circuit 300 of FIG. 3, a word line driver 402 and sense amplifier 404 are shown which, when a word line is accessed, provide a count value (e.g., XCount) RH1 Bits to a counter circuit 408. The counter circuit 408 updates the count value by adding a signal RAS Bits from an oscillator counter circuit 406. The functions of the word line driver 402, sense amplifier 404, oscillator 406 and counter circuit 408 may generally match the equivalent components of FIG. 3, and for the sake of brevity the details and options (such as the omission of the oscillator, or setting RAS Bits to 1 in the test mode) described with respect to FIG. 3 will not be repeated, although they also apply to the embodiment FIG. 4.

The counter circuit 408 provides an updated count value RH1_Count as a multi-bit number. The PRACT circuit includes a multiplexer 420 which receives a first portion of the bits of the updated count value at one input terminal and a second portion of the bits of the updated count value at the other input terminal. For example, if the updated count value is an N bit number (e.g., RH1_Count<N−1:0>), then the first input terminal may receive the most significant bits RH1_MSB (e.g., RH1_Count<N−1:M>) and the second input terminal may receive the least significant bits RH1_LSB (e.g., RH1_Count<M−1:0>). In some embodiments, if the count value does not divide evenly (e.g., there are an odd number of bits) an extra digit may be added, such as a 0 appended to the beginning of one of the portions. For example, if the count value RH1_Count is an 11 bit number, then RH1_MSB may be the five most significant bits with a 0 in front (e.g., RH1_MSB<0, RH1_Count<10:6>>) and RH1_LSB may be RH1_Count<5:0>.

The multiplexer has a select terminal coupled to PRACT_En. When the signal PRACT_En is inactive, the most significant bits of the updated count value RH1_MSB is provided as comparison bits RH1_Comp. When the signal PRACT_En is active, the least significant bits of the updated count value RH1_LSB is provided as the comparison bits RH1_Comp.

The comparator circuit 410 compares a threshold portion AT_MSB to the comparison bits RH1_Comp. Since the comparison bits RH1_Comp represent a portion of the count value, the threshold portion AT_MSB may represent a portion of the bits of the threshold value AT. The threshold may be programmed in (e.g., by a mode register setting, a fuse setting, or other setting of the memory) as a multi-bit number which matches a number of bits of the count value RH1 Bits. However, since the updated count value is split into portions, only a portion of the threshold which matches a number of bits of the two portions RH1_MSB and RH1_LSB may be provided to the comparator. The portion AT_MSB may represent the most significant bits of the threshold AT.

Since the input values AT_MSB and RH1_Comp may represent portions of the values AT and RH1_Counter, the comparator 410 may compare fewer bits than the comparator 310 of FIG. 3. If the value of the count value portion RH1_Comp is greater than or equal to the value of the threshold portion AT_MSB then the signal RH1_AT_Flag (e.g., Agg) is provided.

In the normal mode, the MSB of the updated count value RH1_MSB is compared to the MSB of the threshold AT_MSB. In the PRACT mode, the LSB of the updated count value RH1_LSB is compared to the MSB of the threshold AT_MSB. When the LSB of the count is compared to the MSB of the threshold, far fewer activations are required before the LSB of the count value exceeds the threshold. However, unlike the example embodiment of FIG. 3, the value of the threshold itself remains unchanged between the normal and PRACT modes.

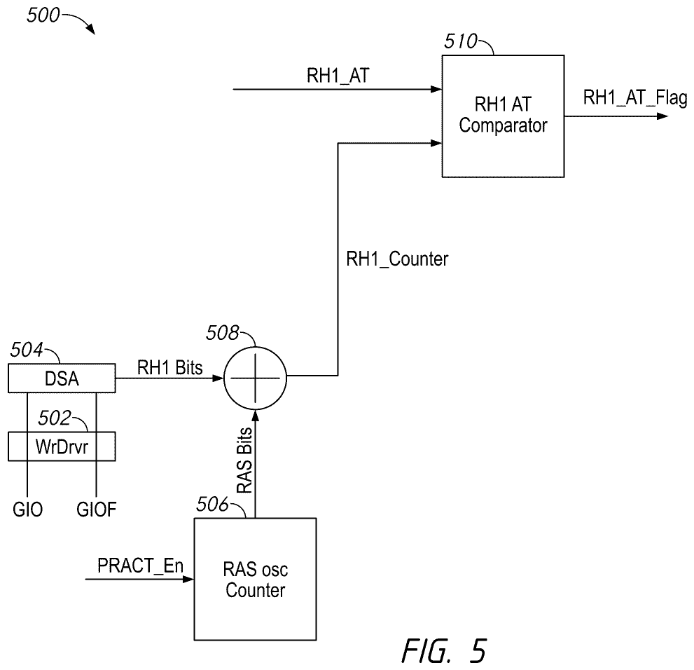

FIG. 5 is a schematic diagram of an aggressor detector circuit with a PRACT circuit which modifies how much the count value is adjusted according to some embodiments of the present disclosure. The aggressor detector circuit 500 may, in some embodiments, implement the aggressor detector circuit 116 of FIGS. 1 and/or 217 of FIG. 2. The aggressor detector circuit 500 shows an example implementation where the PRACT circuit (e.g., 252 of FIG. 2) includes the oscillator 506, which has a modified behavior when the signal PRACT_En is active.

FIG. 5 shows a word line driver 502, sense amplifier 504, counter circuit 508, and comparator 510 all of which may be generally similar to the word line driver 302, sense amplifier 304, counter circuit 308, and comparator 310 of FIG. 3. They may also be similar to the equivalent components of FIG. 4, although unlike FIG. 4, the counter 508 provides the full updated count value RH1_Counter to the comparator 510, and the comparator 510 compares the full threshold RH1_AT to the updated count value RH1_Counter. For the sake of brevity details and optional features already described with respect to FIGS. 3 and/or 4 will not be repeated again with respect to FIG. 5.

In the embodiment of FIG. 5, the oscillator circuit 506 has modified behavior compared to the oscillator counter circuits 306 and 406 of FIGS. 3 and 4. When the signal PRACT_En is inactive (e.g., at a logical low), the oscillator circuit 506 functions in a manner similar to the way it functions in the embodiments of FIGS. 3 and 4. When the signal PRACT_En is inactive, the oscillator circuit 506 provides the signal RAS Bits with a value of one when the word line is first activated, and then increments the value of RAS Bits with timing based on a periodic oscillating signal. However, when the signal PRACT_En is active (e.g., at a logical high), the oscillator circuit 506 provides RAS Bits at a set value which is greater than one. For example, when the signal PRACT_En is active, the oscillator 506 may provide RAS Bits at its maximum value. For example, if the signal RAS Bits is a 7 bit number, then when PRACT_En is active it may be provided with a value of 127, the signal RAS Bits is an 8 bit number then when PRACT_En is active it may be provided with a value of 255, and so forth.

In this manner, when this signal PRACT_En is active, each time a word line is activated, the maximum value of RAS Bits is added to the count value RH1 Bits. This may relatively rapidly increase the count value per access, which means that in the PRACT mode fewer accesses (and/or less time) is required for the updated count value to reach the threshold RH1_AT.

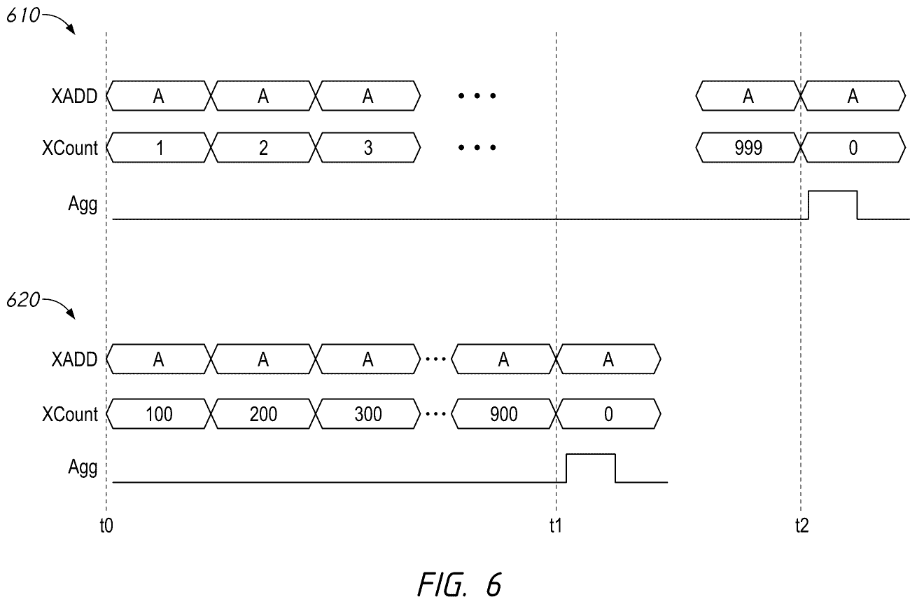

FIG. 6 is a timing diagram of example behaviors of an aggressor detector circuit according to some embodiments of the present disclosure. The timing diagrams 610 and 620 of FIG. 6 may, in some embodiments, represent the operations of a refresh control circuit such as 116 of FIGS. 1 and/or 216 of FIG. 2, specifically the aggressor detector circuit such as 217 of FIG. 2, 300 of FIG. 3, 400 of FIG. 4, and/or 500 of FIG. 5. In particular, the timing diagrams 610 and 620 may represent the operations of an embodiment similar to embodiment of FIG. 5, where when the PRACT mode is active, a larger value is added to the FIG. 6 shows a timing diagram 610 which represents the operation of an aggressor detector in a normal operational mode and a timing diagram 620 which represents the operation of the same aggressor detector in a PRACT mode. The two timing diagrams are shown side by side to allow comparison of the relative timing, although the two diagrams 610 and 620 may represent the operation of the same circuit at different points in time. The two diagrams 610 and 620 each show a row address, which in this case shows an example pattern of repeated access to a row address ‘A’. The diagrams also show the count value XCount (e.g., RH1 bits of FIGS. 3-5) associated with that row and the aggressor signal Agg (e.g., RH1_AT_Flag of FIGS. 3-5).

At an initial time t0, both timing diagrams 610 and 620 initialize with the count values at an initial value before they start receiving access operations to the row A. In the timing diagram 610, when the row A is accessed, the count value XCount is increased by one. In the timing diagram 620, when the row A is accessed, the count value XCount is increased by 100 (e.g., because the oscillator is providing the signal RAS Bit at the value of 100). At the time t1, the chart 620 shows that the signal Agg becomes active because the count value XCount reaches the threshold 1000 and is reset. At a later time t2, the chart 610 shows the signal Agg becoming active. It may take more activations for the signal Agg to become active in the normal mode (e.g., diagram 610) than in the PRACT mode (e.g., diagram 620).

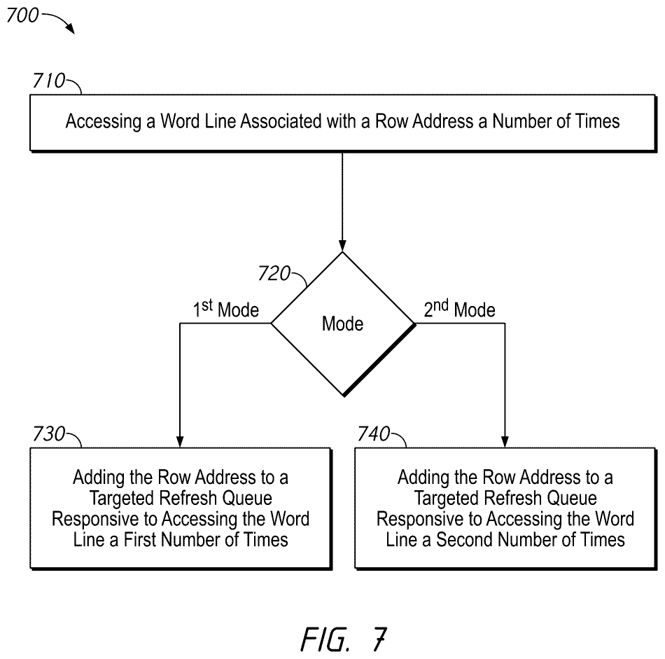

FIG. 7 is a flow chart of a method according to some embodiments of the present disclosure. The method 700 may, in some embodiments, be implemented by one or more of the apparatuses or systems described herein. For example, the method 700 may be performed by the memory device 100 of FIG. 1, the memory of FIG. 2, and/or one of the aggressor detector circuits 300 of FIG. 3, 400 of FIG. 4, and/or 500 of FIG. 5.

The method 700 may include box 710, which describes accessing a word line associated with a row address a number of times. For example, the method 700 may include receiving the row address and an access command and accessing the word line with a row decoder (e.g., 108 of FIGS. 1 and/or 208 of FIG. 2) responsive to the row address and access command. The method 700 may include receiving the row address and access command from a controller of the memory.

The method 700 may include reading a count value from counter memory cells (e.g., 126 of FIGS. 1 and/or 226 of FIG. 2), changing the count value, and writing the count value back to the counter memory cells responsive to each of the access operations.

Box 710 is followed by box 720, which describes determining a mode of the memory device 720. The mode may be determined based on a PRACT register of the memory. For example, the method 700 may include providing a PRACT enable signal (e.g., PRACT_En of FIGS. 1-5) in a first state if the PRACT register is in a first state and providing the PRACT enable signal in a second state if the PRACT register is in a second state.

Box 720 is followed by box 730 in the first mode and box 740 in the second box. Box 730 describes adding the row address to a targeted refresh queue (e.g., 244 of FIG. 2) responsive to accessing the word line a first number of times in the first mode and box 740 describes adding the row address to the targeted refresh queue responsive to accessing the word line a second number of times in the second mode.

For example, the method 700 may include comparing the changed count value to a threshold, and providing an aggressor signal responsive to the changed count value crossing the threshold. The method 700 may include adding the row address to the targeted refresh queue responsive to the aggressor signal.

In an example embodiment, the method 700 may include setting a first value as threshold in the first mode or setting a second value as the threshold in the second mode (e.g., with the multiplexer 320 of FIG. 3). In an example embodiment, the method 700 may include comparing a first portion of the changed count value to a first portion of the threshold in the first mode or comparing a second portion of the changed count value to the first portion of the threshold in the second mode (e.g., with the multiplexer 420 of FIG. 4). In an example embodiment, the method may include changing the count value by adding a first value to the count value in the first mode or a second value to the count value in the second mode. The method 700 may include changing the first value over time in the first mode, but providing the second value as a fixed value in the second mode (e.g., with the oscillator counter circuit 506 of FIG. 5).

In some embodiments, the method 700 may include performing a test on the memory device. The method 700 may include entering the device into the second mode (e.g., a PRACT mode), accessing the word line the second number of times, and determining if the row address was added to the targeted refresh queue.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
an targeted refresh queue configured store a row address responsive to an aggressor signal;
an aggressor detector circuit configured to provide the aggressor signal after a first number of times that the row address is accessed in a first mode and configured to provide the aggressor signal after a second number of times that the row address is accessed in a second mode.

2. The apparatus of claim 1, wherein the aggressor detector circuit includes a test circuit configured to change the behavior of the aggressor detector circuit based on a state of a test mode enable signal, wherein the test mode enable signal is in a first state in the first mode and a second state in the second mode.

3. The apparatus of claim 1, wherein the aggressor detector circuit comprises:
a counter circuit configured to change a count value associated with the row address responsive to the row address being accessed; and
a comparator circuit configured to compare the changed count value to a threshold and provide the aggressor signal if the changed count value has crossed the threshold.

4. The apparatus of claim 3, wherein the aggressor detector circuit further comprises:
a multiplexer configured to provide a first value as the threshold in the first mode or a second value as the threshold in the second mode.

5. The apparatus of claim 3, wherein the aggressor detector circuit further comprises:
a multiplexer configured to provide the most significant bits of the count value as a comparison value in the first mode or the least significant bits of the count value as the comparison value in the second mode,
wherein the comparator circuit is configured to compare the comparison bits to the most significant bits of the threshold.

6. The apparatus of claim 3, wherein the counter circuit is configured to change the count value by adding a first value to the count value in the first mode or by adding a second value to the count value in the second mode.

7. The apparatus of claim 6, wherein the aggressor detector circuit further comprises an oscillator counter circuit configured to provide the first value based on a count of oscillations of an oscillator in the first mode or the provide the second value as a fixed value in the second mode.

8. A method comprising:
accessing a word line associated with a row address a number of times; and
adding the row address to a targeted refresh queue responsive to accessing the word line a first number of times in a first mode or a second number of times in a second mode.

9. The method of claim 8, further comprising:
changing a count value associated with the word line responsive to accessing the word line;
comparing the changed count value to a threshold;
adding the row address to the targeted refresh queue based on the comparison of the changed count value to the threshold.

10. The method of claim 9, further comprising:
setting a first value as the threshold in the first mode; and
setting a second value as the threshold in the second mode.

11. The method of claim 9, further comprising:
comparing a first portion of the changed count value to a first portion of the threshold in the first mode or comparing a second portion of the changed count value to the first portion of the threshold in the second mode.

12. The method of claim 9, further comprising:
changing the count value by adding a first value to the count value in the first mode or by adding a second value to the count value in the second mode.

13. The method of claim 12, further comprising:
changing the first value over time in the first mode, wherein the second value is a fixed value in the second mode.

14. The method of claim 8, further comprising:
entering a memory device into the second mode;
accessing the word line the second number of times; and
determining if the row address was added to the targeted refresh queue.

15. An apparatus comprising:
a memory array comprising a word line configured to store a count value associated with the word line;
a counter circuit configured to add a first amount to the count value when the word line is accessed in a first mode and configured to add a second amount to the count value when the word line is accessed in a second mode to generate an updated count value; and
a comparator circuit configured to compare the updated count value to a threshold and provide an aggressor signal if the updated count value has crossed the threshold; and
a targeted refresh queue configured to add a row address associated with the word line responsive to the aggressor signal.

16. The apparatus of claim 15, wherein the first mode is a normal operational mode and the second mode is a per row activation counter test (PRACT) mode.

17. The apparatus of claim 15, further comprising:
an oscillator counter circuit configured to provide an access time signal, wherein the access time signal has a value based on a count of oscillations of an oscillating signal in the first mode and wherein the access time signal has a fixed value in the second mode,
wherein the counter circuit is configured to add the access time signal to the count value to generate the updated count value.

18. The apparatus of claim 17, wherein the oscillator counter circuit is configured to provide the access time signal with a maximum value in the second mode.

19. The apparatus of claim 15, further comprising a mode register configured to store a per row activation counter test (PRACT) register, wherein a state of the PRACT register determines if the apparatus is in the first mode or the second mode.

20. The apparatus of claim 15, wherein the word line includes a plurality of counter memory cells configured to store the count value.
